(19) United States
(12) Patent Application Publication
(10) Pub. No.: US 2023/0180489 A1
(43) Pub. Date: Jun. 8, 2023

(54) PHOTO DETECTOR

(71) Applicant: National Taiwan University, Taipei (TW)

(72) Inventors: Ching-Fuh Lin, Taipei (TW); Zih-Chun Su, Taipei (TW); Jen-Yao Chang, Taipei (TW)

(21) Appl. No.: 18/070,025

(22) Filed: Nov. 28, 2022

(30) Foreign Application Priority Data
Dec. 6, 2021 (TW) 110145523

(51) Int. Cl. H10K 30/00; H10K 30/81; H10K 71/40; H10K 85/30

(52) U.S. Cl. CPC H10K 30/354; H10K 30/81; H10K 71/40; H10K 85/331; H10K 2102/20

(57) ABSTRACT

A photo detector is provided with a metal, a semiconductor, a first electrode, and a second electrode. In addition, a pre-treatment and/or a post-treatment is performed to the photo detector to reduce its noise and hence improves the signal-to-noise ratio (SNR). The provided photo detector can quickly respond to short mid-infrared light and generate low noise and high SNR currents.

### CROSS-REFERENCE TO RELATED APPLICATIONS

The entire contents of Taiwan Patent Application No. 110145523, filed on Dec. 6, 2021, from which this application claims priority, are expressly incorporated herein by reference.

### BACKGROUND OF THE INVENTION

### 1. Field of the Invention

The present invention relates to a photo detector.

### 2. Description of Related Art

In 1959, H Y Fan and A K Ramdas et al. found that after a semiconductor is irradiated with light, electrons or holes originally in the semiconductor valence band are excited by incident photons and then jump to the conduction band to form electron-hole pairs or hot carriers, and this mechanism is called mid band-gap absorption (MBA). To make the incident light excite an electron-hole pair, the energy of the incident photon needs to be larger than the energy gap of semiconductor, so that the carrier can obtain sufficient energy to surpass the energy gap of semiconductor and form a photocurrent. At present, photodetectors widely utilize this semiconductor mid band-gap absorption mechanism.

Current infrared sensors mostly use semiconductors with small energy gaps such as III-V or Ge as the active layer or detection-absorbing material to detect infrared light with a small photon energy. Although existing III-V or Ge detectors have been well-established in their manufacturing process, these materials are more expensive than others, and the process requires many complex and expensive epitaxial devices. The principle of such devices is mostly mid band-gap absorption (MBA). Carriers in the semiconductor are excited by incident light and surpass the semiconductor bandgap to generate photocurrents. Therefore, in order to improve the detection efficiency or the responsivity of the device, such components often need to incorporate complex multiple quantum wells (MQWs) or multiple quantum dots (MQDs) in the active layer.

Traditional silicon-based detectors detect light with wavelength bands that are generally limited by the energy gap of silicon. Only light with wavelengths below 1.1 microns can be detected, while light in short mid-infrared light (1-5 microns) cannot. The applicant's previous TW patent (application No. 107116340) discloses a photo detector with metal/semiconductor junction, which can detect short mid-infrared light with a response time up to several seconds. FIG. 1A shows a time-varying dark currents of the photodetector shown in FIG. 2 of the above-identified patent without irradiation and with a bias voltage of 0.2V. FIG. 1B shows a time-varying photocurrents of the photodetector shown in FIG. 2 of the above-identified patent with irradiation and with a bias voltage of 0.2V. As shown in FIGS. 1A and 1B, it takes several seconds, e.g., about 3-5 seconds, to obtain a readable signal. With a bias voltage applied, the photocurrents increase slightly over time. As shown in FIG. 1B, a function f(T) is obtained by curve fitting the experimental data. In addition, another function can also be obtained in the same way for the photodetector of FIG. 1A, which has not been irradiated. Table 1 lists the photocurrent fluctuations of the photo detector shown in FIG. 2 of the above-mentioned patent, where the phot detector is not illuminated and bias voltages of 0, −0.2V, and −0.3V are respectively applied. As illustrated in FIG. 1B, the current fluctuations is calculated from the following formula:

$$fluctuation = \sqrt{\frac{{( Δ {I}_{1} )}^{2} + {( Δ {I}_{2} )}^{2} + … {( Δ {I}_{n} )}^{2}}{n}} ,$$

wherein n denotes the number of data, ΔI₁=|I₁−Iₜ₁|, ΔI₂=|I₂−Iₜ₂| . . . ΔIₙ=|Iₙ−Iₜₙ|.

TABLE 1

| | Current fluctuations without irradiation |
|---|---|
| bias | (mA) |
| 0 | 0.0001848 |
| −0.2 | 0.0004846 |
| −0.3 | 0.0009178 |

### SUMMARY OF THE INVENTION

According to some embodiments of the present invention, a photo detector includes a semiconductor, a metal, a first electrode, and a second electrode. The lower surface of the metal is in contact with the upper surface of the semiconductor. The first electrode is in contact with the upper surface of the metal. The second electrode forms ohmic contact with the lower surface of the semiconductor. After thermal equilibrium, the Fermi level of the metal differs from the conduction or valence band of the semiconductor by less than or equal to 0.2 eV.

According to some embodiments of the present invention, a photo detector includes a semiconductor, a metal, a first electrode, and a second electrode. The lower surface of the metal is in contact with the upper surface of the semiconductor. The first electrode is in contact with the upper surface of the metal. The second electrode forms ohmic contact with the lower surface of the semiconductor. Carriers in the metal layer or the semiconductor layer are excited by incident photons to form hot carriers crossing the metal/semiconductor junction to generate a photocurrent. Under the same conditions, a fluctuation of the generated photocurrents and the dark current of the photo detector is less than 0.009 μA.

In the photo detectors provided by this invention, because the difference between the Fermi level of the metal and the conduction band or valence band of the semiconductor is quite small after thermal equilibrium, carriers can easily cross the energy barrier at the metal/semiconductor junction. Therefore, the provided photo detectors can rapidly detect light in a wide range of wavelengths. Preferably, the provided photo detector is pre-processed and/or post-processed to reduce noise, thereby improving the signal-to-noise ratio (SNR) and enabling the photo detector to have the described properties.

In some embodiments, the pre-processing (pretreatment) includes one or more of the following: changing the material of the first and/or the second electrode; adding an insulating layer between the metal and the semiconductor; adding a multi-layer structure between the metal and the semiconductor; forming a surface resonance structure on the surface of the semiconductor, and adding an insulating layer or a multi-layer structure between the metal and the surface resonance structure.

In some embodiments, the post-treatment includes one or more of the following: annealing; surface filtering; and surface anti-reflection treatment.

The provided photo detectors can detect light in the wavelength ranging from visible light 300 nm to long wavelength 20 μm, as well as reducing noise of the photocurrents and improving the response speed. In addition, the provided photo detectors have low manufacturing cost and can be mass-produced. The manufacturing of which is preferably silicon-based for ease of integration with other silicon-based devices.

### BRIEF DESCRIPTION OF THE DRAWINGS

FIGS. 1A and 1B show the time-varying dark currents and photocurrents of a photodetector in accordance with applicant's previous research.

FIG. 2 shows an energy band diagram of a photo detector in accordance with an embodiment of the present invention.

FIG. 3 shows an energy band diagram of a photo detector in accordance with another embodiment of the present invention.

FIG. 4 shows a photo detector in accordance with an embodiment of the present invention.

FIG. 5 shows a measurement system in accordance with an embodiment of the present invention.

FIG. 6 shows the time-varying currents of the photo detector in accordance with an embodiment of the present invention.

FIG. 7A shows a time-varying currents of a photo detector (without insulating layer) in accordance with an embodiment of the present invention, and FIG. 7B shows a time-varying currents of the photo detector (with insulating layer) in accordance with an embodiment of the present invention.

FIG. 8 shows the time-varying currents of the photo detector, with different bias voltages being applied, in accordance with an embodiment of the present invention.

FIG. 9 shows a photo detector according to another embodiment of the present invention.

FIG. 10A shows a photo detector according to another embodiment of the present invention.

FIG. 10B shows the absorption spectrum of the photo detector shown in FIG. 10A.

FIG. 11 shows a photo detector according to another embodiment of the present invention.

FIG. 12 shows the frequency responses of the photo detector shown in FIG. 4 and a commercial photodetector.

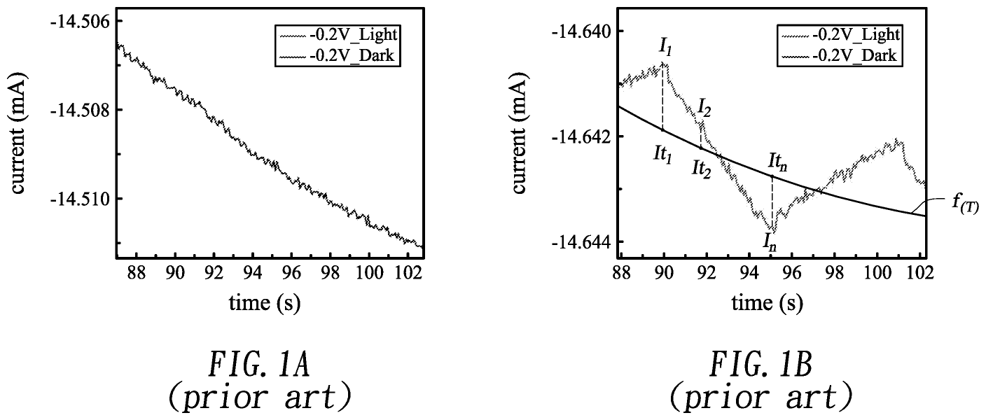

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention.

Some embodiments of the present invention provide a photo detector including a semiconductor, a metal, a first electrode, and a second electrode. A lower surface of the metal is in contact with an upper surface of the semiconductor. The first electrode is in contact with an upper surface of the metal. The second electrode forms ohmic contact with a lower surface of the semiconductor. Carriers in the metal or the semiconductor are excited by incident photons to form hot carriers crossing the junction between the metal and the semiconductor to generate a photocurrent. Under the same conditions, both fluctuations of the photocurrent and a dark current of the photo detector are less than 0.009 μA.

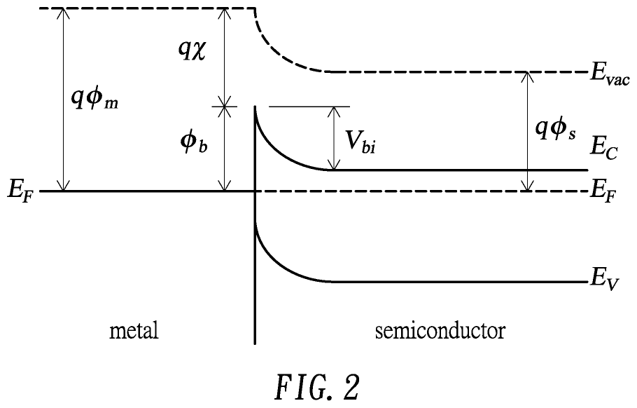

FIG. 2 shows an energy band diagram of a photo detector provided by an embodiment of the present invention. In the exemplary embodiment, the photo detector includes the above-mentioned structure, wherein the semiconductor is an n-type semiconductor, and the main carriers are electrons. The metal and semiconductor each have its own energy band, Fermi level, and energy gap before contacting with each other. The energy gap (Eg) of the semiconductor is the energy difference between the conduction band (Ec) and the valence band (Ev). The work function is defined as the energy difference between the Fermi level and the vacuum level (Evac). The electron affinity q_{χ} of the semiconductor is the energy difference between conduction band E_{c} and semiconductor vacuum level E_{vac}. The work function (Om) of metal is greater than that of semiconductor (qϕs). As shown in FIG. 2, a thermal equilibrium is reached after metal and semiconductor contact with each other, and in an ideal state, the Fermi levels of metal and semiconductor are equal. If the main carrier electrons in the n-type semiconductor are needed to flow to the metal, the built-in electric field V_{bi} at the junction must be overcome. If the main carrier electrons in the metal are needed to flow to the semiconductor, the barrier height ϕb at the junction must be overcome. The barrier height ϕb is the energy difference between the Fermi level and the conduction band of the semiconductor at band edge with majority carriers. In some embodiments of the present invention, the barrier height ϕb is less than or equal to 0.2 eV. In some embodiments, the barrier height ϕb is less than or equal to 0.15 eV. In some embodiments, the barrier height ϕb is less than or equal to 0.1 eV. Therefore, the carrier can easily overcome the energy barrier at the metal-semiconductor junction, so the photodetector can detect light in a wide wavelength range and hence improve the response speed.

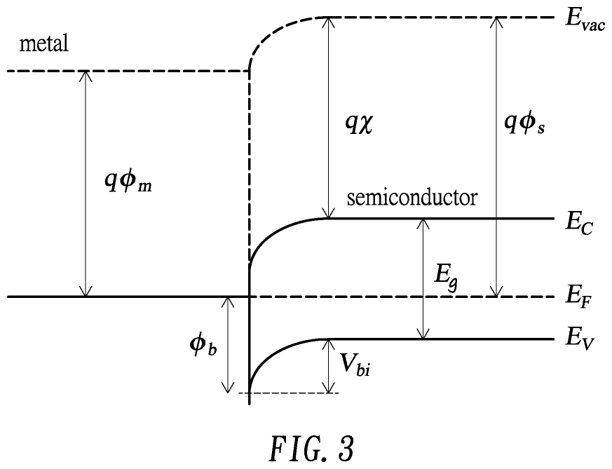

FIG. 3 shows an energy band diagram of a photo detector in accordance with an embodiment of the present invention. In the exemplary embodiment, the semiconductor is a p-type semiconductor, and the main carriers are holes. The work function (Om) of the metal is smaller than the work function (qϕs) of the semiconductor.

As shown in FIG. 3, the metal and the semiconductor reach thermal equilibrium after contacting with each other, and ideally, the Fermi levels of the metal and the semiconductor are equal. If the main carrier holes (h⁺) in the semiconductor are needed to flow to the metal, the built-in electric field V_{bi} at the junction must be overcome. If the main carrier holes (h⁺) in the metal are needed to flow to the semiconductor, the barrier height ϕb at the junction must be overcome. The barrier height ϕb is the energy difference between the Fermi level and the conduction band of the semiconductor at band edge with majority carriers. In some embodiments of the present invention, the barrier height ϕb is less than or equal to 0.2 eV. In some embodiments, the barrier height ϕb is less than or equal to 0.15 eV. In some embodiments, the barrier height ϕb is less than or equal to 0.1 eV. Therefore, the carrier can easily overcome the energy barrier at the metal-semiconductor junction, so the photodetector can detect light in a wide wavelength range and hence improve the response speed.

In some embodiments, the photo detector can detect incident light with wavelengths ranging from 300 nm to 20 μm. In some embodiments, the photo detector is used to detect incident light with wavelengths ranging from 3 μm to 8 μm. In some embodiments, a pre-treatment and/or a post-treatment is performed on the photo detector to reduce its noise and hence improves the signal-to-noise ratio (SNR), thereby enabling the photo detector to have the described properties. The provided photo detector can quickly respond to short mid-infrared light and generate low noise and high SNR currents.

In some embodiments, the pretreatment includes one or more of the following: changing the material of the first and/or the second electrode; adding an insulating layer at the interface between the metal and the semiconductor; adding a multi-layer structure at the interface between the metal and the semiconductor; forming a surface resonance structure on the surface of the semiconductor and adding an insulating layer or a multi-layer structure between the metal and the surface resonance structure.

In some embodiments, the post-treatment includes one or more of the following: annealing, surface filtering, and surface anti-reflection treatment.

In some embodiments, the pre-treatment of the photo detector includes forming an insulating layer, e.g., an oxide layer, between the metal and the semiconductor. The insulating layer can reduce the noise of the photo detector and improve the signal-to-noise ratio of the measured currents. The photocurrents fluctuation as the temperature rising and falling and the noise of the photo detector itself both can be suppressed. Therefore, photocurrents with small fluctuation becomes obvious and can be observed.

In some embodiments, the thickness of the insulating layer is less than or equal to 30 nm. In some embodiments, the thickness of the insulating layer is less than or equal to 20 nm. In some embodiments, the metal is made of gold, silver, copper, chromium, or nickel, and the thickness of the metal is less than 100 nm. In some embodiments, the thickness of the insulating layer is less than 10 nm, such that the insulating layer effectively suppresses noise and does not affect the carriers at the metal/insulator/semiconductor junction to cross the energy barrier to generate photocurrent.

The barrier height ϕb can be estimated by current-voltage (IV-curve) or capacitance-voltage (CV-curve) measurements.

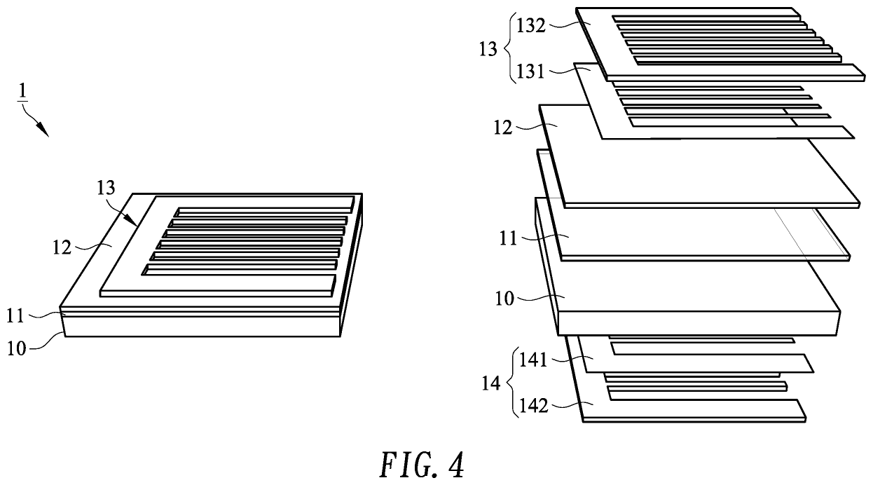

FIG. 4 shows a photo detector 1 according to an embodiment of the present invention. The photo detector 1 is subjected to a pre-treatment by adding an insulating layer between the metal and the semiconductor to enable the photo detector having the described properties. The production of which is described below.

First, a semiconductor substrate 10, such as a silicon substrate, is cut into a square with a side length 2.5 cm. Next, the cut silicon substrate is immersed in a buffered oxide etchant (BOE) to etch the silicon dioxide naturally formed on its surface. The presence or absence of a residual oxide layer can be confirmed through the hydrophobicity of the surface of the silicon substrate.

Next, a piranha solution is prepared by sulfuric acid and hydrogen peroxide in a ratio of 4:1 and then heated to 50° C.

Next, the silicon substrate is horizontally placed into the piranha solution. Due to the hydrophobicity of the surface of the silicon substrate, the silicon substrate will float on the piranha solution. After a period, such as 60, 120, 180 seconds, a silicon substrate with an insulating layer 11 (SiO₂) on its one surface can be obtained. The longer the etching time, the thicker the insulating layer 11. The insulating layer 11 is not limited to silicon dioxide in other embodiments.

Next, a metal layer 12 with a thickness of 10 nm, such as chromium (Cr), is deposited on the insulating layer 11 with an electron gun (E-gun). In some embodiments, the metal layer 12 is made of gold, silver, copper, chromium, nickel, or a combination thereof, with a thickness less than 100 nanometers. Next, the first electrode 13 and the second electrode 14 are respectively deposited on the surface of the metal layer 12 and the bottom surface of the semiconductor substrate 10 with the electron gun (E-gun). The first electrode 13 and the second electrode 14 may include metal bonding layers 131/141 and conductive layers 132/142. In some embodiments, metal bonding layers 131/141 may not be required. The first electrode 13 may have finger or other patterns, and it is used to conduct electricity and transmit light. In the exemplary embodiment, the metal bonding layers 131/141 are titanium finger electrodes with a thickness of 10 nm, and the conductive layers 132/142 are gold finger electrodes with a thickness of 90 nm. In some embodiments, the metal bonding layer 141 and the conductive layer 142 need not be finger-shaped and may be rectangular.

Referring to FIG. 4, in another specific example, the semiconductor substrate 10 is a silicon substrate, the metal layer 12 is made of silver (Ag), the first electrode 13 is made of silver (including only the conductive layer 132, not including the metal bonding layer 131), the insulating layer 11 is made of silicon dioxide, and the second electrode 14 is made of aluminum (including only the conductive layer 142, not including the metal bonding layer 141).

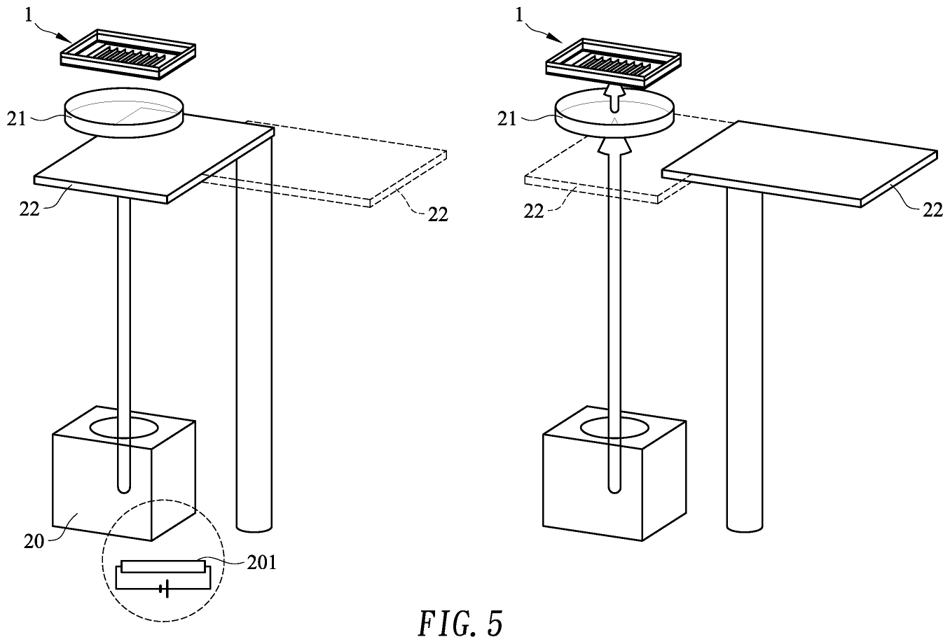

FIG. 5 shows a measurement system according to an embodiment of the present invention. Referring to FIG. 5, an infrared light source 20 includes a ceramic heater 201 connected to a power supply. A current of 0.33 amperes is applied to the ceramic heater 201 to heat its surface temperature to at least 220° C., so that it can emit short infrared light. In the exemplary example, the ceramic heater 201 is heated to a surface temperature of 330° C. to emit light in the short mid-infrared wavelength band (2 μm to 20 μm). In addition, a filter 21, such as a calcium fluoride filter, is placed between the fabricated photo detector 1 and the infrared light source 20. And a shutter 22 is arranged between the infrared light source 20 and the filter 21. The shutter 22 can be rotated to move out (open) or move in (close) between the infrared light source 20 and the filter 21. The opening/closing period of the shutter 22 is set to 12 seconds/15 seconds.

The above-mentioned measurement system is placed in a dark box, which is evacuated to eliminate the interference caused by thermal convection to the measurement. A power meter with a program is used to record the generated currents of the photo detector 1 over time. In another embodiment, components such as the infrared light source 20 and the photo detector 1 shown in FIG. 5 are arranged horizontally. This arrangement is expected to eliminate the interference caused by thermal convection to the measurement and hence not necessary for vacuuming.

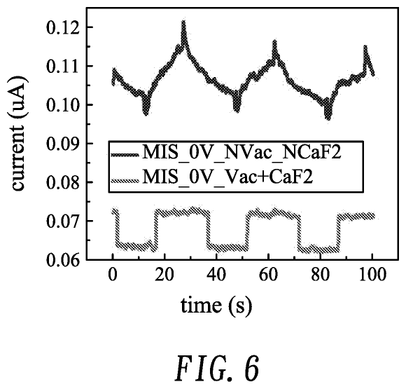

FIG. 6 shows the time-varying currents of the photo detector 1. The measurement system shown in FIG. 5 is used with the test conditions: a bias voltage of 0V applied, vacuumed, and the filter placed between the light source and the photo detector. In addition, the currents under the conditions of applying a bias voltage of 0V, no vacuuming, and no filter (MIS_0V_NVac_NCaF2) were also recorded. It can be observed from FIG. 6 that the currents of the photo detector 1 has a rapid and obvious difference with or without the short mid-infrared light irradiated.

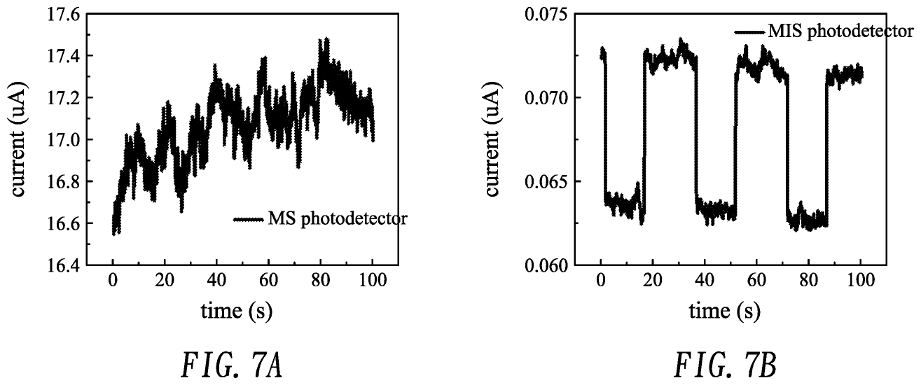

FIG. 7A shows time-varying currents of the photo detector (without insulating layer 12) shown in FIG. 4, wherein the measurement system of FIG. 5 is used to record the currents. FIG. 7B shows time-varying currents of the photo detector (with insulating layer) shown in FIG. 4. Comparing the measured data with and without the insulating layer, it is proved that the photo detector constructed by metal/insulating layer/semiconductor can quickly respond to the incident mid-infrared light.

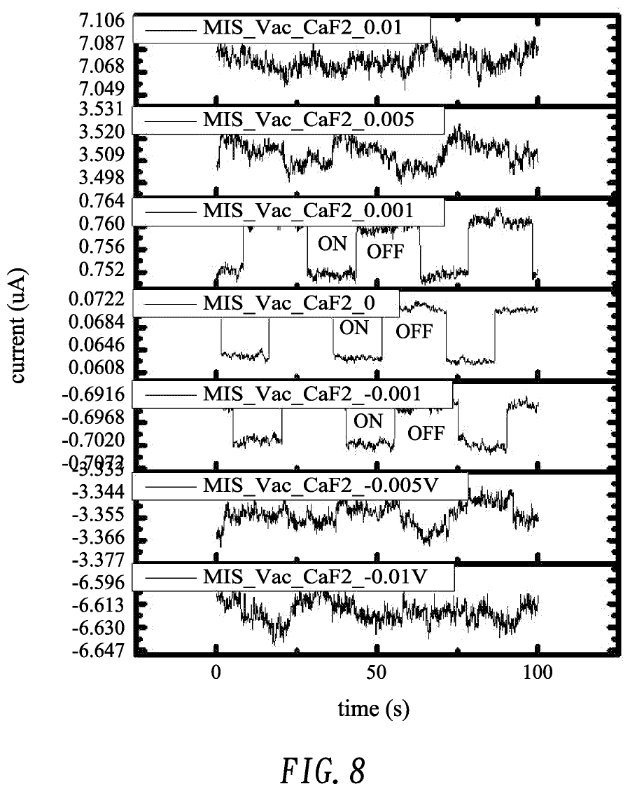

FIG. 8 shows the time-varying currents of the photo detector 1 shown in FIG. 4 under different bias voltages (0.01V, 0.005V, 0.001V, 0V, −0.001V, −0.005V, −0.01V). The measurement system shown in FIG. 5 is used. The opening/closing period of the shutter 22 is set to 12 seconds/15 seconds. Table 2 lists the photocurrent fluctuation, overall signal fluctuation, and signal-to-noise ratio with bias voltages of 0.001V, 0V, and −0.001V. The photocurrent signal is divided into with-irradiation (ON) and without-irradiation (OFF). The photocurrent amplitude is defined as: Ion-Ioff (absolute value can be taken), where Ion is the average of all photocurrents with-irradiation, and Ioff is the average of all photocurrents without-irradiation. The overall signal fluctuation has the same definition as “current fluctuations” in Table 1, except that the photocurrent amplitude should be deducted for all photocurrents with-irradiation. The signal-to-noise ratio is the ratio of the photocurrent amplitude to the overall signal fluctuation.

TABLE 2

| | photocurrent | overall signal | |
|---|---|---|---|
| | amplitude | fluctuation | |
| Bias | (μA) | (μA) | signal-to-noise ratio |
| 0.001 | 0.00904 | 1.155e−03 | 7.823 |
| 0 | 0.00882 | 7.512e−04 | 11.748 |
| −0.001 | 0.00898 | 1.324e−03 | 6.783 |

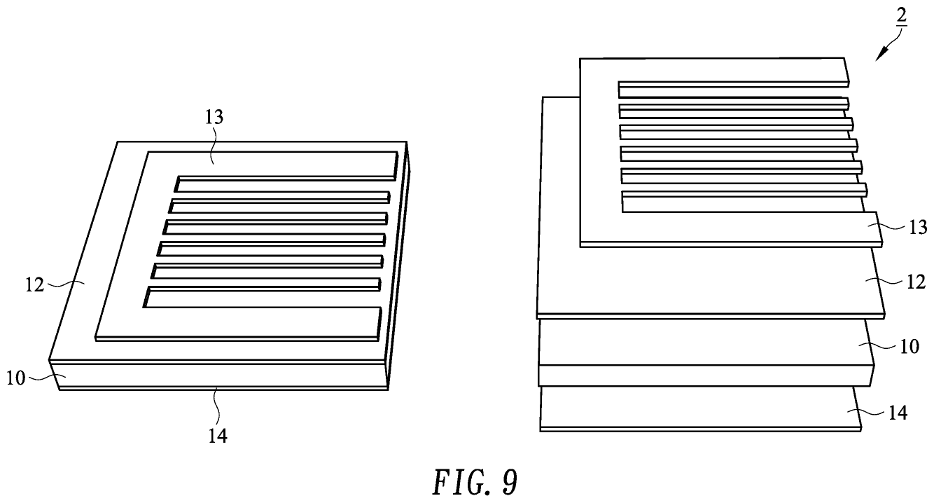

FIG. 9 shows a photo detector 2 according to an embodiment of the present invention, in which the first and/or second electrode is made of different material in the pretreatment to enable the photo detector 2 having the mentioned characteristics. The photo detector 2 is similar to the photo detector 1 shown in FIG. 4, except that it does not include an insulating layer. Referring to FIG. 9, the photo detector 2 includes: a semiconductor layer 10; a metal layer 12 with a lower surface in contact with an upper surface of the semiconductor layer 10; a first electrode 13 in contact with an upper surface of the metal layer 12; and a second electrode 14 forming an ohmic contact with a lower surface of the semiconductor layer 10.

In one exemplary embodiment shown in FIG. 9, the semiconductor layer 10 is made of silicon, the metal layer 12 is made of chromium (Cr), the first electrode 13 is made of chromium, and the second electrode 14 is made of platinum (Pt). In another embodiment, the semiconductor layer 10 is made of silicon, the metal layer 12 is made of silver (Ag), the first electrode 13 is made of silver, and the second electrode 14 is made of platinum (Pt) or aluminum (Al). In another embodiment, the semiconductor layer 10 is made of silicon, the metal layer 12 is made of chromium (Cr), the first electrode 13 is made of chromium, and the second electrode 14 is made of aluminum.

Table 3 lists the noise fluctuation of: the photodetector of FIG. 2 of the mentioned TW patent (application no. 107116340) previously applied by the applicant, the photodetector 1 shown in FIG. 4, and the photodetector 2 shown in FIG. 9 of this invention, with different bias voltages applied. Referring to Table 3, by selecting the materials, the photo detector 2 can also have a low noise fluctuation. After thermal equilibrium, the difference between the Fermi level of the metal layer and the conduction band or valence band of the semiconductor layer of the photodetector 2 is less than or equal to 0.2 eV.

TABLE 3

| | noise | noise | noise |
|---|---|---|---|
| | fluctuation | fluctuation | fluctuation |
| | of previous | of photo | of photo |
| Bias volatge | study | detector 1 | detector 2 |
| (V) | (μA) | (μA) | (μA) |
| −0.010 | 0.11855 | 6.70E−3 | 3.70098E−3 |
| −0.005 | 0.12516 | 3.35E−3 | 2.27234E−3 |
| −0.001 | 0.13796 | 1.03E−3 | 1.43969E−3 |
| 0.000 | 0.13038 | 5.08E−4 | 1.05914E−3 |
| 0.001 | 0.13157 | 8.76E−4 | 1.11326E−3 |
| 0.005 | 0.14781 | 4.17E−3 | 5.10506E−3 |
| 0.010 | 0.12596 | 6.57E−3 | 5.88435E−3 |

Referring to Table 3, compared to the applicant's previous patent TW107116340, the photo detector of the present invention can quickly respond to short and mid-infrared incident light, without forming micro/nano structures on the surface of the semiconductor.

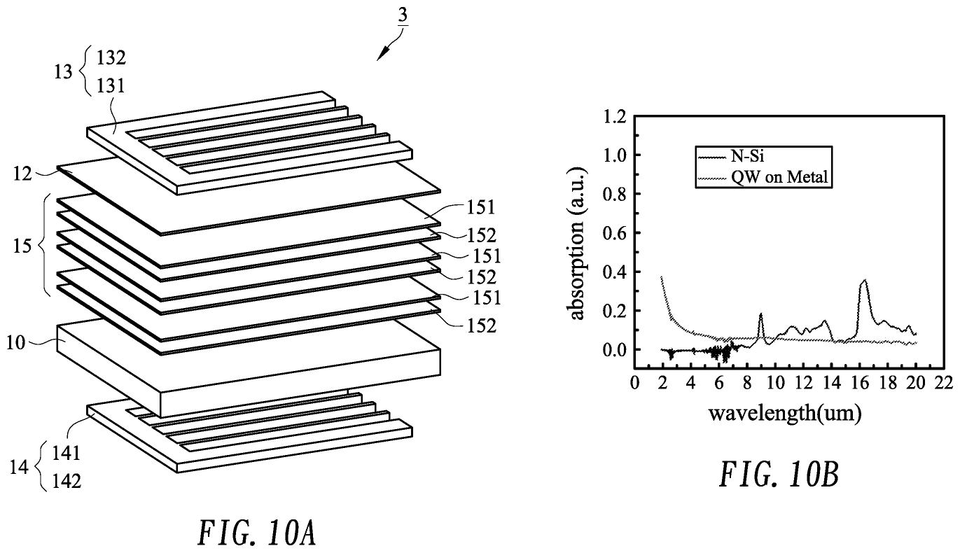

FIG. 10A shows a photo detector 3 according to another embodiment of the present invention. The difference between the photo detector 3 and the photo detector 1 of FIG. 4 is that the insulating layer 11 is replaced by a multilayer structure 15 between the semiconductor layer 10 and the metal layer 12. The multilayer structure 15 may include alternating first layers 151 and second layers 152. In some embodiments, the thicknesses of both the first layer 151 and the second layer 152 are less than 10 nanometers, the total number of the first layer 151 and the second layer 152 is between 6 and 20, and the total thickness of the multilayer structure 15 is between 60 nm and 200 nm. The other components of the photo detector 3 can be the same as those of the photo detector 1 described in FIG. 4. In one embodiment, the first layer 151 is made of silicon, the second layer 152 is made of germanium, the semiconductor substrate 10 is a silicon substrate, the metal layer 12 is made of chromium, and the metal bonding layers 131/141 are titanium fingers with a thickness of 10 nm, and the conductive layers 132/142 are gold finger electrodes with a thickness of 90 nm. In some embodiments, the metal bonding layer 141 and the conductive layer 142 need not be finger-shaped and may be rectangular. In some embodiments, the metal bonding layers 131/141 may not be required.

FIG. 10B shows the absorption spectrum of the photo detector 3 of FIG. 10A. As shown in FIG. 10B, the multi-layer structure 15 helps to improve the absorption of the photo detector 3 in the wavelength range of 2-6 In FIG. 10B, the black line (N—Si) is the absorption spectrum of a pure silicon substrate. Due to the limitation of the energy gap, the silicon cannot absorb light in the wavelength range of 2-6 microns. The green line (QW on Metal) is the absorption spectrum of the photo detector 3. Due to the multi-layer structure 15, the absorption in the wavelength range of 2-6 microns is increased by 20-40%.

In some embodiments, a pre-treatment is further performed on the photo detector shown in FIG. 4, FIG. 9 or FIG. 10A. For example, a surface resonance structure is formed on the surface of the semiconductor substrate 10 and an insulating layer 11 or a multi-layer structure 15 is formed between the metal layer 12 and the surface resonance structure. The surface resonance structure may comprise, but not limited to, those structures described in FIGS. 9A to 10 and 23 of TW patent (application number 107116340) previously applied by the applicant, e.g., an inverted pyramid array or an upright pyramid array formed on the surface of the semiconductor. The experimental result show that in the wavelength range of 2-5 microns, the photocurrent of the photo detector with the surface resonance structure is amplified by 5.5 times compared with the photo detector without the surface resonance structure.

In some embodiments, the photo detector shown in FIG. 4, FIG. 9, or FIG. 10A is post-processed, e.g., annealed. The annealing process will affect the characteristics of the material surface and improve the interface stress problem due to the lattice mismatch when different materials are evaporated. In some experiments, the annealing was performed for three photodetectors where the metal layer 12 are made of different metals (silver/chromium/nickel), and the annealing temperature was controlled in the range of 200-700° C. with the period within 5 minutes. The experimental results show that the annealing temperature of 500° C. has a better photocurrent enhancement effect for the photo detector whose metal layer 12 is made of nickel. And for the metal layer 12 made of silver and chromium, the annealing temperature controlled at 600° C. and 400° C. allows the photo detector to have the best performance.

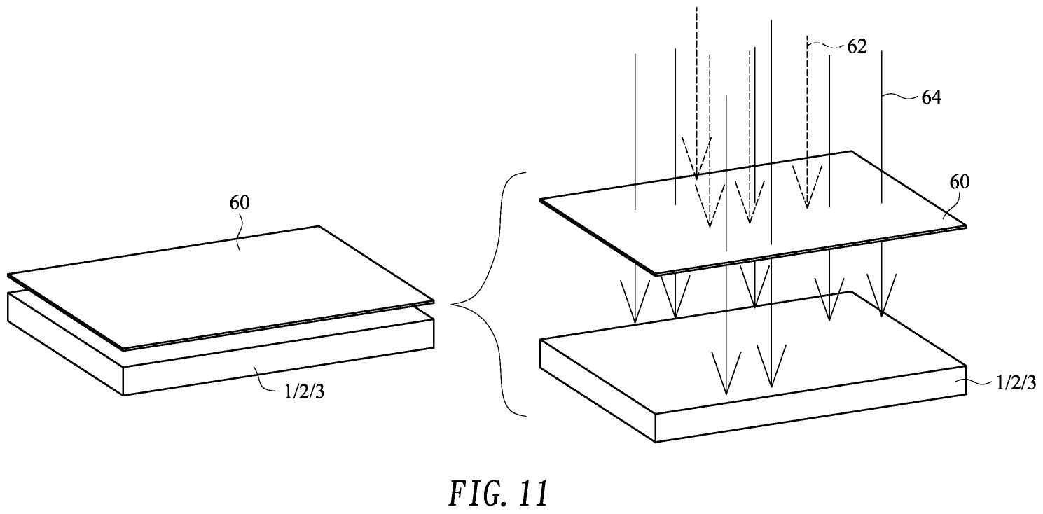

In some embodiments, a post-treatment is performed on the fabricated photo detector, such as the photo detector 1/2/3 shown in FIG. 4, 9 or 10A. For example, FIG. 11 shows that one or more filter films 60 are formed on the surface of the photo detector 1/2/3. The unwanted wavelength bands of the ambient light 62 are filtered out through the energy gap of the filter material, and only the target light 64 with the desired wavelength band can pass through. In some embodiments, a silicon or germanium film is deposited on the surface of the photo detector 1/2/3 to filter out light with wavelengths below 1100 nm or below 2000 nm. Generally, ambient light is in the visible light band, which is easily detected by the photodetector. The filter film 60 filters out the unwanted wavelength bands to reduce noise and improve the signal-to-noise ratio of the measured signals.

In some embodiments, a post-treatment is performed on the fabricated photo detector, such as the photo detector 1/2/3 shown in FIG. 4, 9, or 10A. The photo detector is subjected to surface anti-reflection treatment.

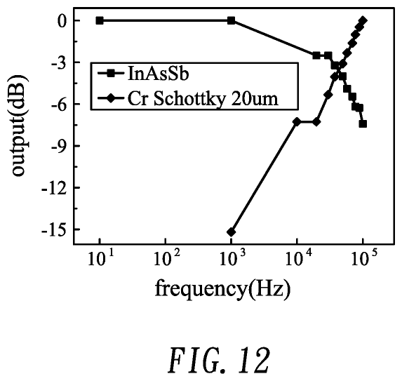

The experimental results show that the photocurrents generated by the provided photo detectors have low noise, which is beneficial to varied applications of timely detection. For example, the photo detectors of this invention can be an optical gas detector or an infrared light detector, which can be applied to detect dangerous gases or to measure body temperature in real time at public places (such as airports), so as to obtain accurate and timely information. In addition, the photo detectors provided by this invention can quickly respond to short mid-infrared light, and the response time is less than 10 microseconds. For example, FIG. 12 is a frequency response analysis of the photo detector shown in FIG. 4 (where the semiconductor substrate 10 is an n-type silicon substrate, the metal layer 12 is chromium, and the conductive layers 132/142 are gold). The horizontal axis is the frequency and the vertical axis is the response output (dB). The frequency represents the reciprocal of the signal period, and the frequency response chart represents the output electrical signal intensities of the photo detector when optical signals with same amplitude and different frequencies are input. From the frequency response chart, the response trend of the photo detector to light with different frequencies can be clearly observed. In FIG. 12, the black line (InAsSb) is the measured frequency response of a commercial III-V compound photodetector (manufactured by Thorlab, model PDA10PT(-EC)), which has a response bandwidth of 25 kHz due to the limitation of circuit design. The red line (Cr Schottky 20 um) shows the measured frequency response of the photo detector shown in FIG. 4. In the frequency range below 100 kHz, the output signal intensity of the photo detector 1 increases with the increase of the frequency, which means that the provided photo detector can perform photoelectric conversion well for signals with a period of less than 10 microseconds. Compared with the commercial III-V compound photodetector, the photo detector provided by this invention reveals a better performance in photoelectric conversion at frequencies higher than kHz or even GHz.

In addition, the manufacturing of the photo detectors provided by this invention is preferably a silicon-based process, which has a low manufacturing cost and facilitates integration with other silicon-based devices.

In addition, the photo detectors provided by this invention have a wide detection wavelength band ranging from visible light 300 nm to mid-infrared light or even 20 μm. In some embodiments, a photo detector provided by this invention is applied to detect light with wavelengths ranging from 3 μm to 8 μm. The provided photo detector is beneficial to detect dangerous gases. Because different gas molecules have different absorption peak wavelengths in the mid-infrared light band, the provided photo detector can detect different gases molecules within a single measurement.

Although specific embodiments have been illustrated and described, it will be appreciated by those skilled in the art that various modifications may be made without departing from the scope of the present invention, which is intended to be limited solely by the appended claims.

What is claimed is:

1. A photo detector, comprising:
a semiconductor layer;
a metal layer, a lower surface of the metal layer being in contact with an upper surface of the semiconductor layer;
a first electrode being in contact with an upper surface of the metal layer; and
a second electrode forming ohmic contact with a lower surface of the semiconductor layer;
wherein carriers in the metal layer or the semiconductor layer are excited by incident photons to form hot carriers crossing a junction between the metal layer and the semiconductor layer to generate a photocurrent, and under a same test condition, a fluctuation of the photocurrent and a dark current of the photo detector is less than 0.009 μA.

2. The photo detector of claim 1, further comprising performing a pre-treatment to the photo detector to reduce noise, and the pre-treatment comprising changing the materials of the first electrode and/or the second electrode.

3. The photo detector of claim 1, further comprising performing a pre-treatment to the photo detector to reduce noise, and the pre-treatment comprising adding an insulating layer at the junction between the metal layer and the semiconductor layer.

4. The photo detector of claim 1, further comprising performing a pre-treatment to the photo detector to reduce noise, and the pre-treatment comprising adding a multi-layer structure at the junction between the metal layer and the semiconductor layer.

5. The photo detector of claim 1, further comprising performing a pre-treatment to the photo detector to reduce noise, and the pre-treatment comprising forming a surface resonance structure on the surface of the semiconductor layer and forming an insulating layer or a multi-layer structure between the surface resonance structure and the metal layer.

6. The photo detector of claim 1, further comprising performing a post-treatment to the photo detector to reduce noise, and the post-treatment comprising annealing the photo detector.

7. The photo detector of claim 1, further comprising performing a post-treatment to the photo detector to reduce noise, and the post-treatment comprising forming one or more filter films on the photo detector to filter out unwanted wavelength bands in ambient light.

8. The photo detector of claim 1, further comprising performing a post-treatment to the photo detector to reduce noise, and the post-treatment comprising performing a surface anti-reflection treatment on the photo detector.

9. The photo detector of claim 1, wherein the photo detector can detect incident light with wavelengths ranging from 300 nm to 20 μm.

10. The photo detector of claim 3, wherein a thickness of the insulating layer is less than or equal to 30 nm.

11. The photo detector of claim 3, wherein the metal layer is made of gold, silver, copper, chromium, nickel, or a combination thereof, and the thickness of the metal layer is less than 100 nm.

12. The photo detector of claim 2, wherein the second electrode is made of platinum or aluminum.

13. The photo detector of claim 12, wherein the metal layer is made of silver or chromium, and the first electrode is made of silver or chromium.

14. The photo detector of claim 4, wherein the multilayer structure comprises alternating first layers and second layers, both thicknesses of the first layer and the second layer are less than 10 nm, a total number of the first layers and the second layers is between 6 and 20, and a total thickness of the multilayer structure is between 60 nm and 200 nm.

15. The photo detector of claim 5, wherein the surface resonance structure comprises an inverted pyramid array or an upright pyramid array.

16. The photo detector of claim 6, wherein the annealing is controlled at temperature between 200° C. and 500° C.

17. The photo detector of claim 1, wherein a response time of the photo detector is less than 10 microseconds.

18. A photo detector, comprising:
a semiconductor;
a metal, a lower surface of the metal being in contact with an upper surface of the semiconductor;
a first electrode being in contact with an upper surface of the metal; and
a second electrode forming ohmic contact with a lower surface of the semiconductor;
wherein, an energy difference between a Fermi level of the metal and a conduction band or valence band of the semiconductor is less than or equal to 0.2 eV after thermal equilibrium.

19. The photo detector of claim 18, wherein the semiconductor is n-type silicon, and the energy difference between the Fermi level of the metal and the conduction band of the semiconductor is less than 0.2 eV.

20. The photo detector of claim 18, wherein the semiconductor is p-type silicon, and the energy difference between the Fermi level of the metal and the valence band of the semiconductor is less than 0.2 eV.

21. The photo detector of claim 18, further comprising performing a pre-treatment to the photo detector to reduce noise, and the pre-treatment comprising one or more of the following:
changing the material of the first electrode and/or the second electrode;
adding an insulating layer between the metal and the semiconductor; adding a multi-layer structure between the metal and the semiconductor; and
forming a surface resonance structure on the surface of the semiconductor, and forming an insulating layer or a multilayer structure between the surface resonance structure and the metal.

22. The photo detector of claim 18, further comprising performing a post-treatment to the photo detector to reduce noise, and the post-treatment comprising one or more of the following:
annealing the photo detector;
depositing one or more filter films on the surface of the photo detector; and
performing an anti-reflection treatment on the surface of the photo detector.
